(19) United States
(12) Patent Application Publication
(10) Pub. No.: US 2026/0173815 A1
(43) Pub. Date: Jun. 18, 2026

(54) CONTROLLING TEMPERATURE UNIFORMITY OF A WAFER USING A WAFER PEDESTAL SHIELDING ELEMENT

(71) Applicant: Applied Materials, Inc., Santa Clara, CA (US)

(72) Inventors: Sajad Yazdani, Fremont, CA (US); Peter Lai, Milpitas, CA (US); Sudhir Ram Gondhalekar, Pleasanton, CA (US); Ralph Peter Antonio, Los Gatos, CA (US); Yi-Fang Jen, Hsinchu City (TW)

(73) Assignee: Applied Materials, Inc., Santa Clara, CA (US)

(21) Appl. No.: 18/978,911

(22) Filed: Dec. 12, 2024

(51) Int. Cl. H01L 21/687; H01L 21/67

(52) U.S. Cl. CPC H10P 72/7611; H10P 72/0432

(57) ABSTRACT

Disclosed herein are approaches for controlling temperature uniformity of a wafer using a wafer pedestal shielding element. In one approach, a wafer support assembly may include a pedestal comprising a first main side opposite a second main side, wherein the first main side is operable to receive a wafer. The wafer support assembly may further include a shielding element adjacent the second main side of the pedestal, the shielding element extending around an outer edge of the pedestal.

### FIELD OF THE DISCLOSURE

The embodiments of the present disclosure relate to wafer temperature uniformity and, in particular, to controlling temperature uniformity of a wafer using a wafer pedestal shielding element.

### BACKGROUND OF THE DISCLOSURE

When processing a wafer on a wafer pedestal, material residues may accumulate on the pedestal adjacent and/or beneath an outer edge of the wafer. This build-up of material residue (e.g., film) causes lower wafer edge temperatures due to the low thermal conductivity and thickness of the deposited material, which leads to temperature non-uniformity and lowering of the deposition yield on the wafer. One current approach for mitigating this temperature variation includes manually scrubbing the pedestal to remove the deposited material residue. However, this approach is inconsistent, time consuming, and labor intensive.

It is with respect to this and other consideration that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a wafer support assembly may include a pedestal including a first main side opposite a second main side, wherein the first main side is operable to receive a wafer. The wafer support assembly may further include a shielding element adjacent the second main side of the pedestal, the shielding element extending around an outer edge of the pedestal.

In another aspect, a wafer support assembly may include a pedestal including a first main side opposite a second main side, wherein the first main side is operable to receive a wafer. The wafer support assembly may further include a shielding element adjacent the second main side of the pedestal, wherein the shielding element extends around an outer perimeter of the pedestal, and wherein the shielding element has an annular shape.

In yet another aspect, a method for locally adjusting a temperature of a wafer pedestal may include providing a pedestal comprising a first main side opposite a second main side, wherein the first main side is operable to receive a wafer. The method may further include positioning a shielding element adjacent the second main side of the pedestal, wherein the shielding element extends around an outer perimeter of the pedestal, and wherein the shielding element has an annular shape.

### BRIEF DESCRIPTION OF THE DRAWINGS

The accompanying drawings illustrate exemplary approaches of the disclosure, including the practical application of the principles thereof, as follows:

FIG. 1A is a first perspective view of a wafer support assembly, according to embodiments of the present disclosure;

FIG. 1B is a second perspective view of the wafer support assembly, according to embodiments of the present disclosure;

FIG. 2 illustrates a cross-sectional side view of the wafer support assembly, according to embodiments of the present disclosure;

FIG. 3 is a perspective view of a support structure for the wafer support assembly, according to embodiments of the present disclosure;

FIG. 4 illustrates a top view of a pedestal of the wafer support assembly, according to embodiments of the present disclosure; and

FIG. 5 is a flow chart of a method for locally adjusting a temperature of a wafer pedestal, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, assemblies, and devices in accordance with the present disclosure will now be described more fully hereinafter with reference to the accompanying drawings, where various embodiments are shown. The methods, assemblies, and devices may be embodied in many different forms and are not to be construed as being limited to the embodiments set forth herein. Instead, these embodiments are provided so the disclosure will be thorough and complete, and will fully convey the scope of the methods to those skilled in the art.

Disclosed herein are approaches for wafer edge temperature regulation to mitigate the effects of material/film accumulation on a wafer support, which occurs as a result of typical wafer processing. As will be described herein, a shielding element may be positioned under an edge of the wafer support, wherein the shielding element may be a ring that is aligned with the area(s) where temperature non-uniformity exists. In some embodiments, the shielding element may include an internal heating element, and may be made from low-emissivity materials such as aluminum (bare or anodized), nickel, stainless steel, tungsten, molybdenum, and ceramics (e.g., aluminum nitride or aluminum oxide).

The shielding element adds extra resistance and reduces net heat and radiation loss from the edge of the wafer support, which in turn increases the wafer edge temperature and improves non-uniformity. For example, if the shielding element temperature approaches the edge temperature of the wafer support, the radiation loss in the edge area approaches zero. In some cases, applying a bias to the internal heating element of the shielding element can be used as an active knob for controlling wafer temperature non-uniformity for each process recipe. In other examples, e.g., for an undesirably high wafer edge temperature, the shielding element may be cooled to provide an active control knob to lower the edge temperature.

Advantageously, embodiments of the present disclosure require neither adjusting the heater mesh pattern within the pedestal, nor adding extra heating and/or backside gas zones, which leads to temperature cross-talk. The shielding element of the present disclosure further helps to lower cost, as there is no need to change existing hardware such as the pedestal, electrostatic chuck, gas lines, electrical components, etc.

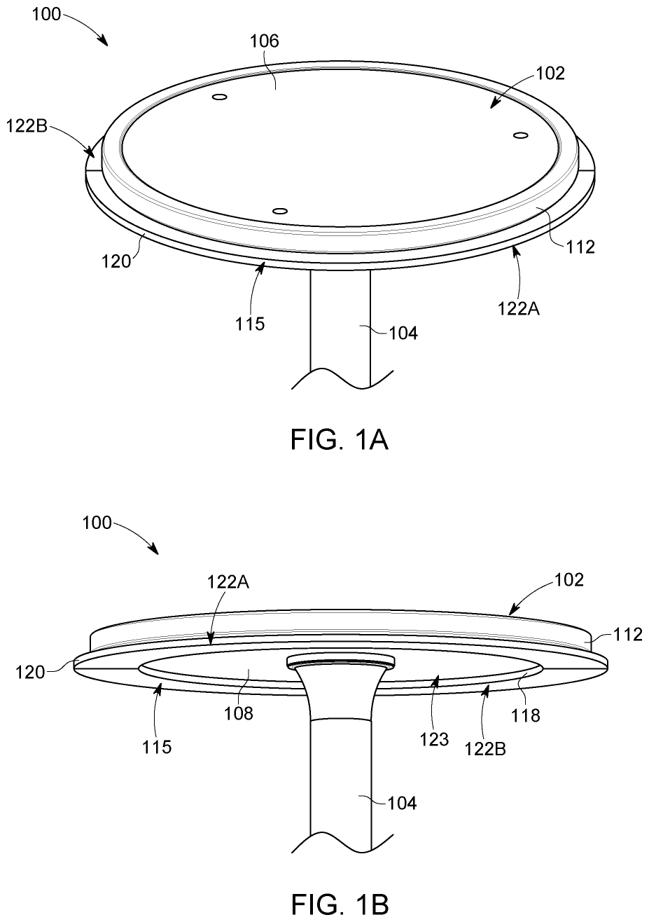

FIGS. 1A and 1B illustrates a wafer support assembly 100 according to embodiments of the present disclosure. The wafer support assembly 100 may include a pedestal 102 extending from a pedestal support 104, the pedestal 102 operable to receive a wafer for processing. Although not shown, the wafer support assembly 100 may be positioned within a process chamber. In some embodiments, the process chamber is suitable for physical vapor deposition (PVD), chemical vapor deposition (CVD), atomic layer deposition (ALD), or the like. However, other types of process chambers configured for different processes, for example, etching, may also be applicable.

The pedestal 102 may include a first main side 106 opposite a second main side 108, wherein the wafer may be positioned directly atop an upper surface of the first main side 106. The pedestal 102 may further include an outer perimeter edge 112. In various embodiments, the wafer may be retained to the pedestal 102 via electrostatic chucking, vacuum chucking, and/or gravity.

The wafer support assembly 100 may further include a shielding element 115 adjacent the second main side 108 of the pedestal 102. As shown, the shielding element 115 may extend around the outer perimeter edge 112 of the pedestal 102. The shielding element 115 may have a substantially annular or ring shape defined by an inner annular perimeter 118 and an outer annular perimeter 120. The shielding element 115 may include two or more sections 122A-B, which can be assembled/disassembled beneath the pedestal 102 as part of a process kit. The shielding element 115 may further define a central opening 123, through which the pedestal support 104 may extend. During use, the shielding element 115 acts as a heat and radiation shield, and may be made from a low-emissivity material, such as aluminum, nickel, stainless steel, tungsten, molybdenum, and/or ceramic.

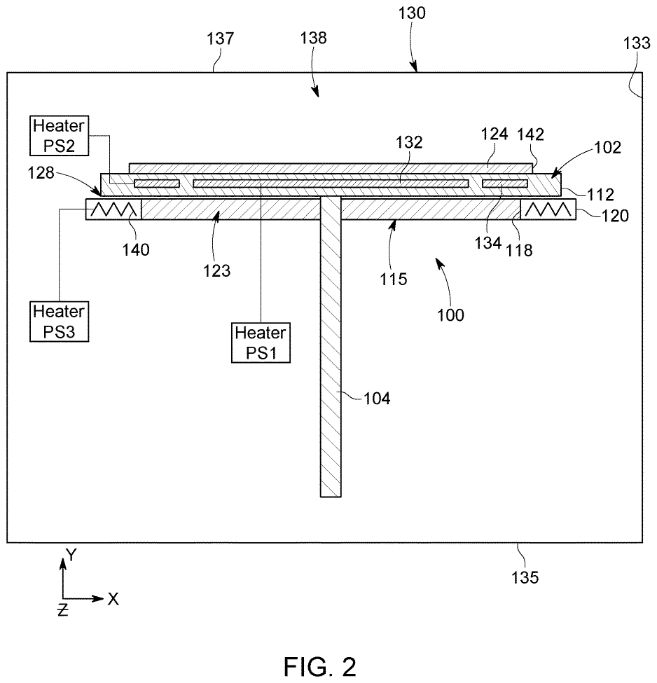

FIG. 2 is a side cross-sectional view of the wafer support assembly 100 within a processing chamber 130. The processing chamber 130 may include a set of sidewalls 133, a bottom 135, and a lid 137, all of which enclose an interior processing region 138 containing the wafer support assembly 100. Although non-limiting, the process chamber 130 may be coupled to, and in fluid communication with, a vacuum system which includes a throttle valve (not shown) and vacuum pump (not shown) which are used to exhaust the process chamber 130. The pressure inside the process chamber 130 may be regulated by adjusting the throttle valve and/or vacuum pump. The process chamber 130 is also coupled to and in fluid communication with a process gas supply which may supply one or more process gases to the process chamber 130 for processing a wafer 124 disposed therein.

As shown, the wafer 124 may be positioned atop the first main side 106 of the pedestal 102, and the shielding element 115 may be positioned along the second main side 108 of the pedestal 102. In the embodiment shown, the shielding element 115 may be separated from the second main side 108 of the pedestal 102 by a physical space or gap 128, which may be adjusted as desired.

In some embodiments, the pedestal 102 may include a first internal pedestal heating element 132 and a second internal pedestal heating element 134. As shown, the first internal pedestal heating element 132 may be positioned in central area of the pedestal 102, while the second internal pedestal heating element 134 is positioned radially farther from the pedestal support 104 than the first internal pedestal heating element 132. As will be described in greater detail herein, the first internal pedestal heating element 132 may include a plurality of heaters arranged in a disc or circular configuration. The second internal pedestal heating element 134 may also include a plurality of heaters. The first internal pedestal heating element 132 is biasable by a first power source (Heater PS1), while the second internal pedestal heating element 134 is biasable by a second power source (Heater PS2). The first and second power sources may be independently biasable to provide power to the respective first and second internal pedestal heating elements 132, 134. Although not shown, a controller may be utilized to control the operation of the first and second power sources, which are generally set to heat the wafer 124 to a desired temperature.

As further shown, the shielding element 115 may include an internal heating element (e.g., a coil or other conductive element(s)) 140 extending circumferentially around the shielding element 115, between the inner annular perimeter 118 and the outer annular perimeter 120. The internal heating element of the shielding element 115 may be biasable by a third power source (Heater PS3). The third power source may also be controlled by the controller, and may be independently biasable.

In some embodiments, the shielding element 115 is generally aligned beneath the outer perimeter edge 112 of the pedestal 102 and beneath a wafer perimeter edge 142 of the wafer 124. More specifically, the wafer perimeter edge 142 may extend laterally (e.g., in the x-direction) beyond the inner annular perimeter 118 of the shielding element 115, and the outer annular perimeter 120 may extend laterally beyond the outer perimeter edge 112. In some embodiments, the outer annular perimeter 120 may extend entirely to the set of sidewalls 133 of the processing chamber 130.

As such, in the case that a material buildup is present along/beneath the wafer perimeter edge 142 of the wafer 124, the position of the shielding element 115 relative to the pedestal 102 causes a local temperature along the wafer perimeter edge 142 to increase, thereby compensating for a drop in temperature along the wafer perimeter edge 142 caused by the material buildup. Furthermore, having the shielding element 115 adjacent the wafer perimeter edge 142 adds extra resistance and reduces the net radiation loss from wafer perimeter edge 142, which increases the wafer edge temperature and improves non-uniformity. Temperature of the wafer perimeter edge 142 can be further adjusted by the internal heating element 140.

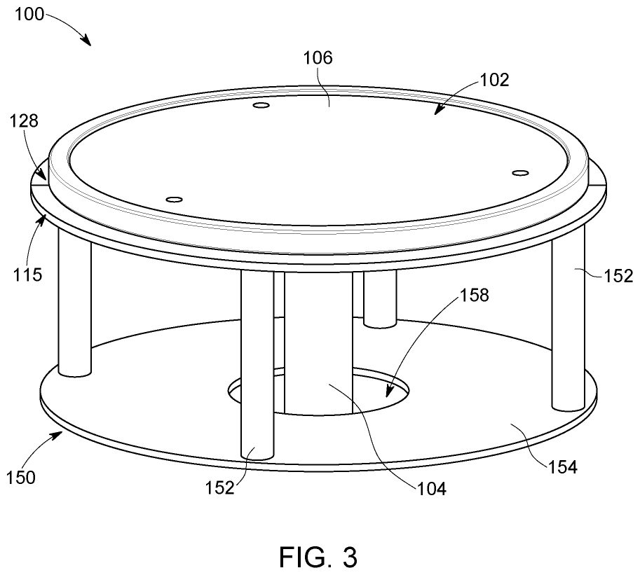

FIG. 3 demonstrates one non-limiting example of a support structure 150 for the shielding element 115. As shown, the support structure 150 may include a plurality of posts 152 extending vertically from a base 154, wherein the shielding element 115 is positioned atop each of the plurality of posts 152. The base 154 may include a central opening 158 through which the pedestal support 104 is received. Although not shown, the base 154 may be coupled to a pedestal hub. During use, the support structure 150 permits the shielding element 115 to be raised and lowered relative to the pedestal 102 to adjust the gap 128 therebetween. It will be appreciated that the support structure 150 shown represents only one possible approach for positioning the shielding element 115 relative to the pedestal 102, and that alternative approaches are possible in other embodiments.

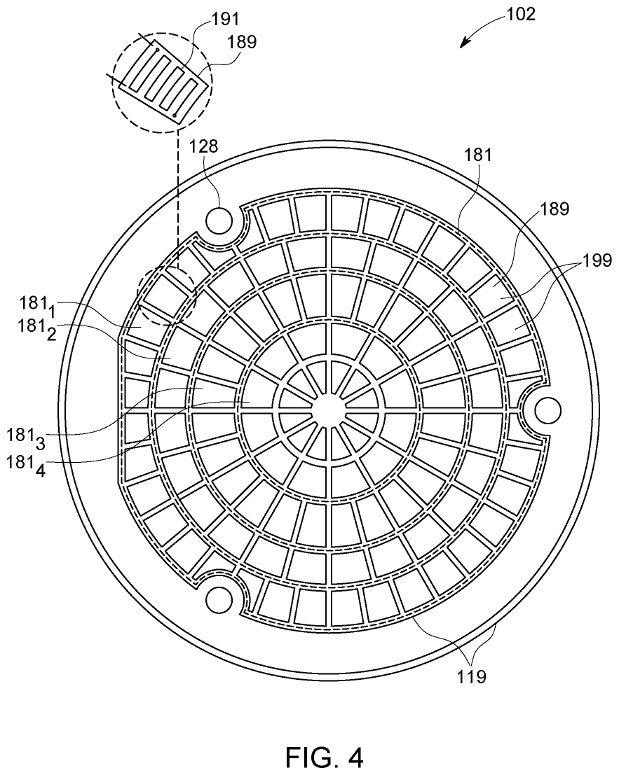

FIG. 4 shows an example arrangement of heating elements within the pedestal 102 according to one or more embodiments. The pedestal 102 may include a plurality of primary resistive heaters, and a plurality of secondary heaters. The primary resistive heaters may be utilized to provide a first/primary thermal application to elevate the temperature of the support assembly pedestal 102 to a temperature suitable for processing the wafer 124.

In one embodiment, the primary resistive heaters are arranged in a plurality of laterally separated heating zones, wherein the controller enables at least one zone of the primary resistive heaters to be individually heated relative to the primary resistive heaters located in one or more of the other zones. For example, the primary resistive heaters may be arranged concentrically in a plurality of radially separated primary heater zones (shown as item 181). In one example, the primary resistive heaters are arranged in four concentric primary heater zones 181, i.e., a first primary heater zone 1811, a second primary heater zone 1812, a third primary heater zone 1813, and a fourth primary heater zone 1814. The first primary heater zone 1811 may correspond to the second internal pedestal heating element 134 described above, while the second primary heater zone 1812, the third primary heater zone 1813, and the fourth primary heater zone 1814 may correspond to the first internal pedestal heating element 132 described above. The embodiments herein are not limited in this context, however. The primary resistive heaters may maintain the wafer 124 at a temperature suitable for processing, such as between about 180 degrees Celsius to about 500 degrees Celsius. When the primary resistive heaters are turned off, the wafer 124 may be at room temperature or ambient temperature, i.e., the temperature within the interior of the processing chamber.

The pedestal 102 may optionally include a plurality of secondary heaters 189. The number of secondary heaters 189 may be an order of magnitude greater than the number of primary resistive heaters. The secondary heaters 189 may provide a secondary thermal application to control the temperature of the pedestal 102 at a micro level, such as plus or minus 5 degrees Celsius, while the primary resistive heaters control the temperature of the pedestal 102 at a macro level. The pedestal 102 may also have a plurality of micro zones, such as 50 to 150 micro zones or more, that are temperature controlled by the secondary heaters 189. The secondary heaters 189 form temperature control in small discrete locations, i.e., micro-zones on the pedestal 102, which is transferred to the wafer 124.

The pedestal 102 of FIG. 4 illustrates one embodiment for the plurality of secondary heaters 189. The secondary heaters 189 may be configured in a pattern to efficiently generate a heat profile along the surface of the wafer 124. The pattern may be symmetric about a midpoint while providing clearance in and around holes for lift pins or other mechanical, fluid or electrical connections. Other patterns or arrangements may be possible in alternative embodiments. The secondary heaters 189 are arranged in a plurality of cells, i.e., micro zones 199. It is contemplated that each secondary heater 189 occupies a respective single micro-zone 199. In some embodiments, a thermal choke 119 may be disposed between each neighboring micro-zone 199. Additionally, the thermal choke 119 may be disposed along an outer perimeter of the pedestal 102. The thermal choke 119 limits heat transfer from adjacent micro zones to prevent heat smearing and true thermal control of each micro-zone 199 by its respective secondary heater 189.

The number of micro zones 199 shown is for illustrative purposes only, and it is contemplated that the number and arrangement of micro zones 199 could exceed 50 or more, such as 150 or more zones. Thus, the number of secondary heaters 189 located across the wafer 124 support assembly 126 may easily be in excess of several hundred. Each micro-zone 199 of the secondary heaters 189 occupies a single one of the primary heater zones 181. A boundary or thermal choke 119 of the micro-zone 199 is coincident with a boundary 182 of a respective primary heater zone 181, for example, the first primary heater zone 1811, such that the micro-zone 199 is fully contained in only the first primary heater zone 1811 and does not extend into the second primary heater zone 1812.

In some embodiments, each secondary heater 189 has a resistor 191 ending in terminals. As current enters one terminal and exists the other terminal the current travels across the wire of the resistor and generates heat. The amount of heat released by the resistor 191 is proportional to the square of the current passing therethrough. The power design density may be between about 1 watt/cell to about 100 watt/cell, such as 10 watt/cell. Embodiments herein are not limited in this context, however.

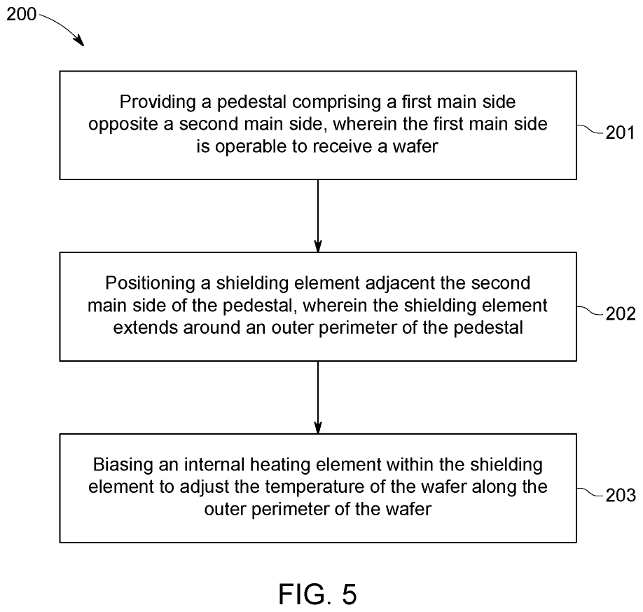

FIG. 5 is a flowchart of a method 200 for locally adjusting a temperature of a wafer pedestal, according to embodiments of the present disclosure. At block 201, the method 200 may include providing a pedestal including a first main side opposite a second main side, wherein the first main side is operable to receive a wafer. In some embodiments, the pedestal is supported by a pedestal support. In some embodiments, the pedestal includes one or more embedded pedestal heating elements. The pedestal, pedestal support, and wafer may be located within a processing chamber.

At block 202, the method 200 may further include positioning a shielding element adjacent the second main side of the pedestal, wherein the shielding element extends around an outer perimeter of the pedestal. In some embodiments, the shielding element may have a substantially annular or ring shape defined by an inner annular perimeter and an outer annular perimeter. The shielding element may include two or more sections, which can be assembled/disassembled beneath the pedestal as part of a process kit. The shielding element may further define a central opening, through which the pedestal support may pass. The shielding element may act as a heat and radiation shield, and may be made from a low-emissivity material, such as aluminum, nickel, stainless steel, tungsten, molybdenum, and/or ceramic. In some embodiments, the shielding element may include an internal heating element extending entirely or partially therethrough. In some embodiments, the shielding element is spaced apart from the second main side of the pedestal by a desired gap.

In some embodiments, at optional step 203, the method 200 may further include biasing the internal heating element within the shielding element to adjust the temperature of the wafer along the outer perimeter of the wafer. More specifically, the temperature along the perimeter of the pedestal can be increased, which in turn increases a temperature of the wafer along a perimeter thereof.

In some embodiments, the method 200 may further include biasing one or more of the heating elements embedded within the pedestal to adjust the temperature of the pedestal. Different portions of the pedestal may be selectively heated, as desired.

In some embodiments, the method 200 may further include moving the shielding ring relative to the pedestal to adjust a gap between the shielding ring and the second main side of the pedestal.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or wafer 124 is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A wafer support assembly, comprising:
a pedestal comprising a first main side opposite a second main side, wherein the first main side is operable to receive a wafer; and
a shielding element adjacent the second main side of the pedestal, the shielding element extending around an outer edge of the pedestal.

2. The wafer support assembly of claim 1, wherein the shielding element comprises an internal heating element.

3. The wafer support assembly of claim 1, wherein the pedestal comprises a first pedestal heating element.

4. The wafer support assembly of claim 3, wherein the pedestal comprises a second pedestal heating element adjacent the first pedestal heating element.

5. The wafer support assembly of claim 4, wherein the first and second pedestal heating elements are independently controllable.

6. The wafer support assembly of claim 1, wherein the shielding element has an annular shape.

7. The wafer support assembly of claim 6, wherein the annular shape is defined by an inner annular perimeter and an outer annular perimeter.

8. The wafer support assembly of claim 7, wherein the outer annular perimeter extends laterally beyond the outer edge of the pedestal.

9. The wafer support assembly of claim 1, wherein the shielding element is made from at least one of the following: aluminum, nickel, stainless steel, tungsten, molybdenum, and ceramic.

10. A wafer support assembly, comprising:
a pedestal comprising a first main side opposite a second main side, wherein the first main side is operable to receive a wafer; and
a shielding element adjacent the second main side of the pedestal, wherein the shielding element extends around an outer perimeter of the pedestal, and wherein the shielding element has an annular shape.

11. The wafer support assembly of claim 10, wherein the shielding element comprises an internal heating element.

12. The wafer support assembly of claim 10, wherein the pedestal comprises a first pedestal heating element and a second heating element, wherein the first and second pedestal heating elements are independently biasable.

13. The wafer support assembly of claim 10, wherein the annular shape is defined by an inner annular perimeter and an outer annular perimeter.

14. The wafer support assembly of claim 13, wherein the outer annular perimeter extends laterally beyond the outer perimeter of the pedestal.

15. The wafer support assembly of claim 10, wherein the shielding element includes multiple sections assembled together, and wherein the shielding element is made from at least one of the following: aluminum, nickel, stainless steel, tungsten, molybdenum, and ceramic.

16. A method of locally adjusting a temperature of a wafer pedestal, the method comprising:
providing a pedestal comprising a first main side opposite a second main side, wherein the first main side is operable to receive a wafer; and
positioning a shielding element adjacent the second main side of the pedestal, wherein the shielding element extends around an outer perimeter of the pedestal, and wherein the shielding element has an annular shape.

17. The method of claim 16, further comprising biasing an internal heating element within the shielding element to adjust a temperature of the wafer along the outer perimeter.

18. The method of claim 16, further comprising biasing one or more pedestal heating elements within the pedestal to adjust the temperature of the pedestal.

19. The method of claim 16, further comprising moving the shielding element relative to the pedestal to adjust a gap between the shielding element and the second main side of the pedestal.

20. The method of claim 16, further comprising connecting a first section of the shielding element to a second section of the shielding element, wherein the shielding element is made from at least one of the following: aluminum, nickel, stainless steel, tungsten, molybdenum, and ceramic.
